(19) United States
(12) Patent Application Publication
(10) Pub. No.: US 2026/0251978 A1
(43) Pub. Date: Aug. 27, 2026

(54) PATTERN FORMING METHOD

(71) Applicant: Resonac Corporation, Tokyo (JP)

(72) Inventors: Kenichi IWASHITA, Tokyo (JP); Keishi ONO, Tokyo (JP); Mao NARITA, Tokyo (JP); Kensuke YOSHIHARA, Tokyo (JP); Kazuyuki MITSUKURA, Tokyo (JP); Kei TOGASAKI, Tokyo (JP); Yuki IMAZU, Tokyo (JP)

(21) Appl. No.: 18/855,833

(22) PCT Filed: May 31, 2022
(86) PCT No.: PCT/JP2022/022203

§ 371 Date: Oct. 10, 2024

(51) Int. Cl. G03F 7/16; G03F 7/00; G03F 7/115; G03F 7/20; H10W 20/00; H10W 70/05

(52) U.S. Cl. CPC G03F 7/168; G03F 7/115; G03F 7/2004; G03F 7/70025; H10W 20/058; H10W 70/05

(57) ABSTRACT

This pattern forming method includes: a laminating step of laminating a curable resin layer and a support film on a substrate; a curing step of curing the entire curable resin layer; a processing step of processing the curable resin layer into a predetermined pattern by irradiating the curable resin layer after curing with excimer laser light from a side of the support film through a mask; a peeling step of peeling the support film from the curable resin layer after processing; and a forming step of forming a plating layer using the curable resin layer after processing as a mask, and then removing the curable resin layer to form a wiring pattern by the plating layer on the substrate.

### TECHNICAL FIELD

The present disclosure relates to a pattern forming method.

### BACKGROUND ART

In recent years, miniaturization, weight reduction, and multi-functionalization of electronic devices have further progressed. Along with this, high integration of LSI, chip components, and the like has progressed, and the forms thereof have also been increased in number of pins and miniaturized. Therefore, high density and high accuracy of semiconductor elements, semiconductor packages, printed wiring boards, flexible wiring boards, and the like constituting these components are required.

Examples of the conventional pattern forming method include a semi-additive process. In this method, an electroless plating layer is formed on an insulating layer, and a resist layer having a predetermined pattern is formed on the electroless plating layer with a photosensitive dry film. Thereafter, an electroplating layer is formed, and peeling of the resist layer and removal of the electroless plating layer are performed to form a wiring having a desired pattern on a substrate. However, there has been a problem that a pattern defect, due to foreign substances, such as particles or adherent matters, contained in a support film (PET film) that supports the photosensitive dry film, becomes noticeable.

In view of such a problem, attention has been paid to a method for forming a pattern using laser ablation processing. For example, in the method for forming a solder resist described in Patent Literature 1, a curable resin in a semi-cured state having a support film is formed on a substrate. Next, the support film is irradiated with laser light to form a via hole in the curable resin in a semi-cured state. Thereafter, the support film is peeled off, and the curable resin layer in a semi-cured state is cured.

### CITATION LIST

### Patent Literature

Patent Literature 1: WO 2012/042846 A

### SUMMARY OF INVENTION

### Technical Problem

However, even in the case of forming a pattern using laser ablation processing as in Patent Literature 1 described above, it is conceivable that the laser light may be refracted in the curable resin in a semi-cured state, leading to a defect in the formed pattern. If a defect occurs in the pattern of the curable resin, the accuracy of a pattern to be formed thereafter may be deteriorated.

The present disclosure has been made to solve the above problems, and an object thereof is to provide a pattern forming method capable of accurately forming a miniaturized pattern.

### Solution to Problem

A pattern forming method according to an embodiment of the present disclosure includes: a laminating step of laminating a curable resin layer and a support film on a substrate; a curing step of curing the entire curable resin layer; a processing step of processing the curable resin layer into a predetermined pattern by irradiating the curable resin after curing with excimer laser light from a side of a support film through a mask; a peeling step of peeling the support film from the curable resin after processing; and a forming step of forming a plating layer using the curable resin layer after processing as a mask, and then removing the curable resin to form a wiring pattern by the plating layer on the substrate.

In this pattern forming method, the entire curable resin layer is cured before the curable resin layer is processed into a predetermined pattern by excimer laser light. This makes it possible to suppress refraction of excimer laser light in the curable resin layer during the processing of the curable resin layer after curing. Also, in this pattern forming method, the curable resin after curing is irradiated with excimer laser light from the side of the support film during the processing of the curable resin layer after curing. Therefore, the support film functions as a protective material for protecting the processed surface of the curable resin layer after curing. Therefore, in this pattern forming method, occurrence of a defect in the curable resin during the processing is suppressed, and a miniaturized pattern can be accurately formed.

A line-and-space L/S of the wiring pattern may be 5/5 μm or less. In this pattern forming method, occurrence of a defect in the curable resin layer in the processing step can be suppressed as described above. Therefore, it is suitable for forming a miniaturized wiring pattern having a line-and-space L/S of 5/5 um or less.

The aspect ratio of the wiring pattern may be 0.5 to 20. In this pattern forming method, occurrence of a defect in the curable resin layer in the processing step can be suppressed as described above. Therefore, it is suitable for forming a miniaturized wiring pattern having an aspect ratio of 0.5 to 20.

The curable resin layer may include a photocurable resin. In this case, the entire curable resin layer can be easily cured by light irradiation.

The curable resin layer may include a thermosetting resin. The entire curable resin layer can be easily cured by heating.

Advantageous Effects of Invention According to the present disclosure, a miniaturized pattern can be accurately formed.

### BRIEF DESCRIPTION OF DRAWINGS

FIG. 1 is a schematic cross-sectional view illustrating a pattern forming structure used in a pattern forming method according to an embodiment of the present disclosure.

FIG. 2 is a flowchart illustrating the pattern forming method according to the embodiment of the present disclosure.

FIG. 3 is a schematic cross-sectional view illustrating a laminating step.

FIG. 4 is a schematic cross-sectional view illustrating a curing step.

FIG. 5 is a schematic cross-sectional view illustrating a processing step.

FIG. 6 is a schematic cross-sectional view illustrating a peeling step.

FIG. 7 is a schematic cross-sectional view illustrating a step subsequent to FIG. 6.

FIG. 8 is a schematic cross-sectional view illustrating a forming step.

FIG. 9 is a schematic cross-sectional view illustrating a step subsequent to FIG. 8.

### DESCRIPTION OF EMBODIMENTS

Hereinafter, a preferred embodiment of a pattern forming method according to one aspect of the present disclosure will be described in detail with reference to the drawings.

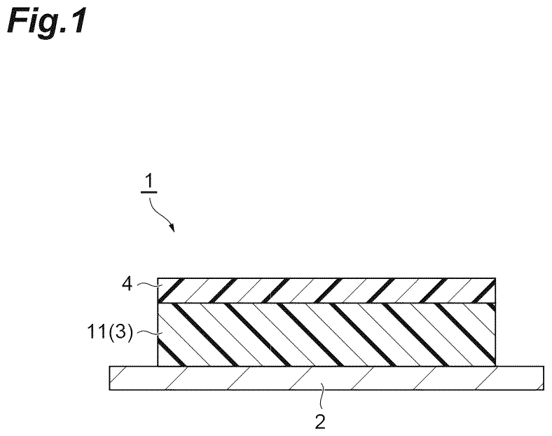

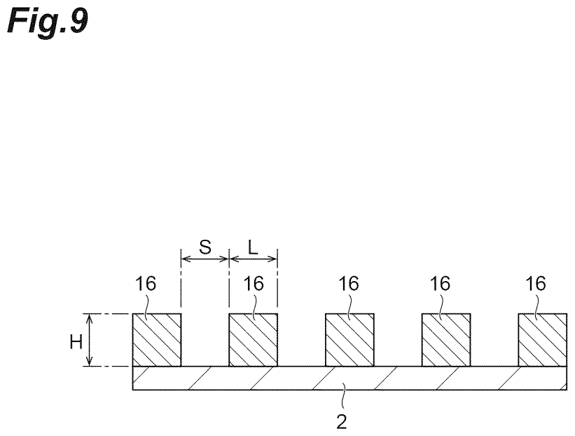

FIG. 1 is a schematic cross-sectional view illustrating a pattern forming structure used in a pattern forming method according to an embodiment of the present disclosure. As illustrated in FIG. 1, a pattern forming structure 1 includes a substrate 2, a curable resin layer 3 laminated on the substrate 2, and a support film 4 laminated on the curable resin layer 3. The substrate 2 is a member on which a wiring pattern 16 (see FIG. 9) is to be formed. The substrate 2 is also an adherend to which the curable resin layer 3 is attached. Examples of the substrate 2 include a silicon wafer, a film-coated silicon wafer on which a metal, such as Cu, is deposited, and a copper-clad laminate.

The curable resin layer 3 includes, for example, a photocurable resin or a thermosetting resin. Here, the curable resin layer 3 includes a negative photocurable resin 11. As the photocurable resin 11, a film-shaped resin may be used, or a liquid resin may be applied for use. The liquid photocurable resin 11 is produced by stirring the respective materials. A stirring (dispersion) method is not particularly limited, but the stirring may be performed by applying heat or the like, or the stirring may be performed under an inert gas atmosphere, a reduced pressure atmosphere, or a pressurized atmosphere. Foreign substances can be removed by filtering the resin composition for which the stirring has been completed. The film-shaped photocurable resin 11 is provided, for example, in a state where a solution of a photocurable resin composition is uniformly applied to a support film and dried.

In order to realize a high etching rate during laser ablation processing to be described later, the photocurable resin 11 is designed in consideration of 1) ease of breakage of molecular bonds during laser light irradiation and 2) absorbability with respect to the wavelength of laser light. To satisfy 1), a compound having lower molecular binding energy is selected. To satisfy 2), a component that absorbs the wavelength of laser light is contained. The photocurable resin 11 contains a polymerizable compound as a component (A), and contains an ultraviolet absorber as a component (B). Any of the component (A) and the component (B) may be contained in a large amount, or may be mixed with other components.

The polymerizable compound is selected on the assumption that the photocurable resin 11 is laminated on the substrate 2 and then polymerized for use. When the photocurable resin 11 is polymerized after lamination, the lamination property or applicability before lamination can be secured, and the tackiness after polymerization can be suppressed. As the polymerizable compound, for example, a compound having a polymerizable ethylenically unsaturated bond in its molecule is used. Examples of the component (A) include a (meth)acrylic resin, urethane acrylate, and epoxy acrylate. The component (A) may be a non-aromatic photopolymerizable compound from the viewpoint of low molecular binding energy. Even when the component (A) is mixed with an aromatic compound or a part of the component (A) contains an aromatic functional group, a high etching rate during the laser ablation processing can be realized by adjusting the ratio.

The ultraviolet absorber is not particularly limited as far as it is a component that absorbs light with a desired wavelength. As the ultraviolet absorber, for example, a known absorber capable of absorbing laser light of ArF (wavelength: 193 nm), KrF (wavelength: 248 nm), XeCl (wavelength: 308 nm), or XeF (wavelength: 351 nm) can be used. Examples of such an absorbent include benzotriazole-based absorbers, triazine-based absorbers, salicylic acid derivative-based absorbers, and benzophenone-based absorbers.

The ultraviolet absorber may have a polymerizable unsaturated group. The ultraviolet absorber is classified into a type that produces radicals when absorbing ultraviolet rays and a type that does not produce radicals when absorbing ultraviolet rays. The ultraviolet absorber of a radical-producing type contains a photoinitiator. When a photoinitiator is contained, the photocurable resin 11 can be cured with ultraviolet rays before and after laser ablation processing, leading to an increase in the handing property of the pattern forming structure 1.

Examples of the photoinitiator include: aromatic ketones such as 2-benzyl-2-dimethylamino-1-(4-morpholinophenyl)-butanone-1 and 2-methyl-1-[4-(methylthio)phenyl-2-morpholino-propanone-1; quinones such as alkyl anthraquinones; benzoin ether compounds such as benzoin alkyl ethers; benzoin compounds such as benzoin and alkyl benzoin; benzyl derivatives such as benzyl dimethyl ketal; 2,4,5-triaryl imidazole dimers such as 2-(o-chlorophenyl)-4,5-diphenyl imidazole dimers and 2-(o-fluorophenyl)-4,5-diphenyl imidazole dimers; and acridine derivatives such as 9-phenyl acridine and 1,7-bis(9,9′-acridinyl)heptane. As the photoinitiator, one of them may be used alone, or two or more thereof may be used in combination.

When the film-shaped photocurable resin 11 is used, the photocurable resin 11 may contain a binder polymer from the viewpoint of film-forming property. The binder polymer is preferably a material having compatibility with the component (A) and the component (B) from the viewpoint of stability during storage. The binder polymer may be a component more flexible than the polymerizable compound of the component (A). This makes it possible to secure the flexibility of the curable resin layer 3 after curing. As the binder polymer, for example, a (meth)acrylic-based resin, a urethane-based resin, an epoxy resin, an amide resin, an amide epoxy resin, an alkyd resin, a polyimide resin, or the like is used. Among these resins, it is preferable to use a (meth)acrylic resin from the viewpoint of contributing to the rate of laser ablation processing, that is, from the viewpoint of low molecular binding energy.

As the binder polymer, it is preferable to select a resin species having a non-aromatic basic skeleton from the viewpoint of low molecular binding energy. Here, the non-aromatic basic skeleton means that the basic skeleton repeated multiple times by polymerization does not contain an aromatic group, and does not mean aromatic groups located only at terminals and the like. It may be good to mix an aromatic binder polymer and an aliphatic polymer to balance with the etching rate.

The molecular weight of the binder polymer varies depending on the state of the photocurable resin 11. When the film-shaped photocurable resin 11 is used, the molecular weight may be selected such that, for example, the film-forming property of the film and the rate of laser ablation processing are balanced. When the molecular weight is sufficiently secured, it is possible to secure the film-forming property and suppress dripping during film formation and storage. When the molecular weight is not made excessive, it is possible to suppress a decrease in the rate of laser ablation processing. When the liquid photocurable resin 11 is used, the rate of laser ablation processing can be increased by designing the liquid photocurable resin 11 to have a low molecular weight as long as application is possible.

The photocurable resin 11 may contain a thermal curing accelerator. The thermal curing accelerator is not particularly limited as far as it can thermally cure the photocurable resin composition, and can be appropriately selected from commonly used thermal curing accelerators. When the thermal curing accelerator is added, the photocurable resin 11 can be cured at a lower temperature, leading to an increase in the handing property of the pattern forming structure 1. Examples of the thermal curing accelerator include imidazoles, dicyandiamide derivatives, dicarboxylic acid dihydrazide, triphenylphosphine, tetraphenylphosphonium tetraphenylborate, 2-ethyl-4-methylimidazole-tetraphenylborate, and 1,8-diazabicyclo[5,4,0]undecene-7-tetraphenylborate. As the thermal curing accelerator, one of them may be used alone, or two or more thereof may be used in combination.

The photocurable resin 11 may contain a polymerization inhibitor. When the photocurable resin 11 contains a polymerization inhibitor, shelf life and work life of the photocurable resin composition are extended. In addition, unnecessary polymerization during laser ablation processing can be suppressed. The unnecessary polymerization referred to herein means that radicals are produced from the photoinitiator by laser light during laser ablation processing, which promotes polymerization. As the polymerization inhibitor, a material having a polymerization inhibition effect on radical polymerization is used. Examples of the polymerization inhibitor include: catechols such as t-butylcatechol; hydroquinones such as hydroquinone, methylhydroquinone, t-butylhydroquinone, and p-methoxyphenol; alkoxyquinones such as methoquinone; and benzoquinones such as p-benzoquinone, methyl-p-benzoquinone, and t-butyl-p-benzoquinone.

The photocurable resin 11 may contain a solvent. When the liquid photocurable resin 11 is used, the photocurable resin 11 preferably contains a solvent from the viewpoint of ease of viscosity adjustment and ease of production and inspection. When the film-shaped photocurable resin 11 is used, the content of the solvent is preferably small. A solvent that cannot be removed in steps such as coating and drying may remain in the photocurable resin 11.

If necessary, the photocurable resin 11 may contain: a dye such as malachite green, Victoria pure blue, Brilliant green, or methyl violet; a photochromic agent such as leucocrystal violet, diphenylamine, benzylamine, triphenylamine, diethylaniline, or o-chloroaniline; a heat-induced coloring inhibitor; a plasticizer such as p-toluenesulfonamide; a pigment; a filler; an antifoaming agent; a flame retardant; a stabilizer; an adhesion imparting agent; a leveling agent; a peeling accelerator; an antioxidant; a fragrance; an imaging agent; a thermal crosslinking agent; or the like. Each of these components can be contained in an amount of, for example, about 0.01 to 20 parts by mass based on 100 parts by mass of the total solid content of the component (A) and the component (B). These materials may be used singly or in combination of two or more thereof.

The support film 4 includes a polymer film having heat resistance and solvent resistance, like polyolefin such as polypropylene or polyethylene, or polyester such as polyethylene terephthalate. Among these films, it is preferable to use a polyethylene terephthalate (PET) film from the viewpoint of transparency. The PET film contains particles for improving fluidity and release property during molding of the PET film. As the particles, for example, inorganic particles such as calcium carbonate, calcium phosphate, silica, kaolin, talc, titanium dioxide, alumina, barium sulfate, calcium fluoride, lithium fluoride, zeolite, and molybdenum sulfide; organic particles such as an ion exchange resin, a crosslinked polymer, and calcium oxalate; and precipitated particles produced during polyester polymerization, can be used.

Next, a pattern forming method using the pattern forming structure 1 described above will be described in detail.

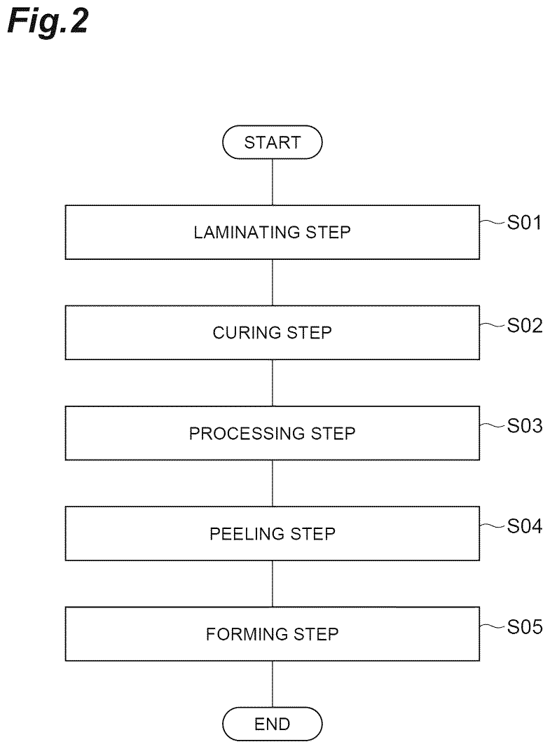

FIG. 2 is a flowchart illustrating the pattern forming method according to an embodiment of the present disclosure. As illustrated in FIG. 2, the pattern forming method includes a laminating step (step S01), a curing step (step S02), a processing step (step S03), a peeling step (step S04), and a forming step (step S05).

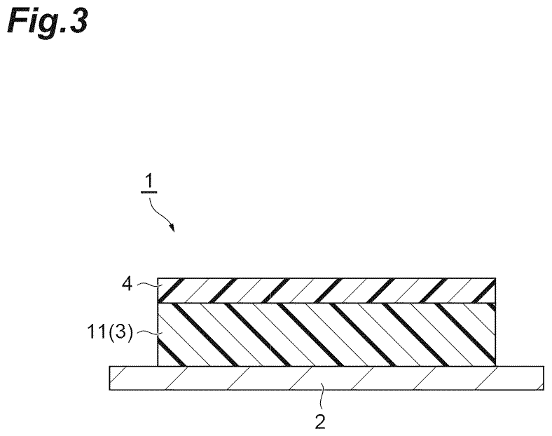

As illustrated in FIG. 3, the laminating step S01 is a step of laminating the curable resin layer 3 and the support film 4 on the substrate 2. The method for the lamination on the substrate 2 varies depending on whether the photocurable resin 11 has a liquid shape or a film shape. When the photocurable resin 11 has a liquid shape, the photocurable resin 11 can be laminated by applying the photocurable resin composition to the substrate 2 and drying the photocurable resin composition. Examples of the method for applying the photocurable resin composition include a spray method, a roll coating method, a spin coating method, a slit die coating method, a bar coating method, an inkjet method, a screen printing method, a gravure coating method, a curtain coating method, and a knife coating method.

The film thickness of the photocurable resin 11 before drying is preferably larger than a target value in consideration of a decrease in the film thickness due to volatilization of the solvent during the drying and the flow of the photocurable resin composition. When the film thickness of the photocurable resin 11 after the drying is further reduced, a large amount of the solvent may be contained in the photocurable resin composition, thereby increasing a decrease rate in the film thickness during the drying by volatilization of the solvent. The solvent residual rate after the drying may be 10 mass % or less, 5 mass % or less, or 2 mass % or less.

The film thickness of the photocurable resin 11 after the drying is, for example, 1 to 200 μm. The film thickness of the photocurable resin 11 after the drying may be 5 to 100 μm or 10 to 50 μm. When the film thickness is set to 1 μm or more, it is industrially easy to realize the coating. When the film thickness is set to 200 μm or less, occurrence of insufficient volatilization of the solvent and appearance abnormality can be suppressed. When the film thickness is set to 100 μm or more, a method can also be adopted, in which the photocurable resin composition is coated with a film thickness of 100 μm or less, and then two or more photocurable resin composition layers are laminated together.

The photocurable resin 11 formed by application or the like may be heated at 50 to 250° C. The heating temperature may be 50 to 200° C. The heating may be performed under an inert atmosphere such as nitrogen, or may be performed under a reduced pressure condition. The drying time is not particularly limited. The drying history may include heating and cooling, or may include a constant temperature. When drying, including heating and cooling, is performed, the surface of the photocurable resin 11 after the drying tends to be flatter.

When the photocurable resin 11 has a film shape, the photocurable resin 11 can be laminated by pressure-bonding the photocurable resin to the substrate 2 while heating the photocurable resin 11. From the viewpoint of adhesion and followability to the substrate 2, the pressure bonding of the photocurable resin 11 may be performed under reduced pressure. The heating temperature may be, for example, room temperature to 130° C. The pressure during the pressure bonding may be, for example, about 0.01 to 1.0 MPa (about 0.1 to 10 kgf/cm² ). In order to further improve the lamination property, a preheating treatment of the substrate 2 and a heating treatment after the lamination may be performed.

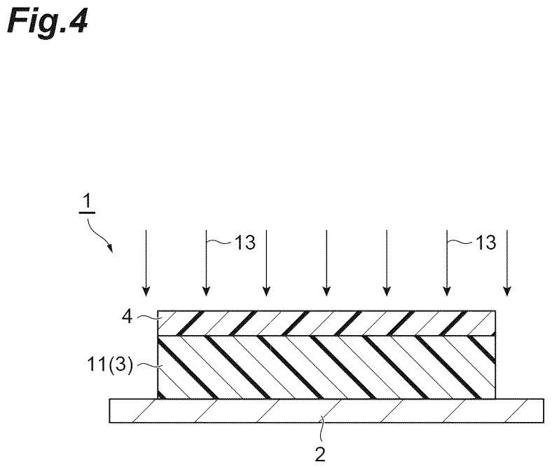

The curing step S02 is a step of curing the entire curable resin layer 3. In the curing step S02, the entire surface of the photocurable resin 11 is irradiated with light 13 through the support film 4 to cure the entire photocurable resin 11, as illustrated in FIG. 4. The light 13 is, for example, ultraviolet light. As a light source of the light 13, for example, an ultraviolet lamp can be used. The irradiation intensity of the light 13 is, for example, 1 to 100 mW. The irradiation time of the light 13 is, for example, 1 to 1000 seconds.

The curing here means that the curable resin layer 3 is completely or almost completely cured. A curing rate F of the curable resin layer 3 after the curing step is performed is, for example, 50% to 100%. The curing rate F may be 85% or more or 90% or more. The curing rate F is calculated by F=((T1−T2)/T1)×100, where T1 is the curing time of the curable resin composition in solution and T2 is the curing time of the curable resin composition after the curing step. The curing time is measured, for example, in accordance with JIS C 6521, item 5.7:“Curing time test”.

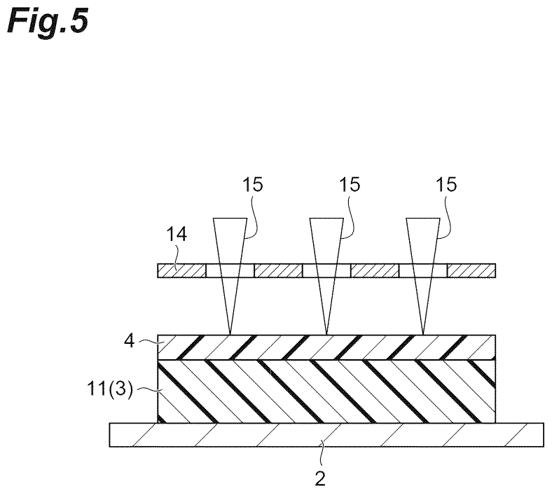

The processing step S03 is a step of processing the curable resin layer 3 into a predetermined pattern. In the processing step, the curable resin layer 3 after curing is irradiated with excimer laser light 15 from the side of the support film 4 through a mask 14, as illustrated in FIG. 5, so that the curable resin layer 3 is processed into a predetermined pattern. That is, in the processing step, laser ablation processing is performed on the curable resin layer 3 after curing, along with the support film 4, using the excimer laser light 15. Here, the curable resin layer 3 after curing is processed into a line shape, and a mask for forming a plating layer in the later forming step S05 is formed on the substrate 2.

Examples of the light source of the excimer laser light 15 include an F2 excimer laser (wavelength: 157 nm), an ArF excimer laser (wavelength: 193 nm), a KrF excimer laser (wavelength: 248 nm), a XeCl excimer laser (wavelength: 308 nm), and a XeF excimer laser (wavelength: 351 nm). In general, the higher the energy density of the excimer laser light 15 per shot on the surface of the curable resin layer 3, the higher the rate of the laser ablation processing. However, when the energy density is equal to or higher than a certain value, the rate of the laser ablation processing is saturated. In consideration of the circumstances described above, the energy density of the excimer laser light 15 per shot on the surface of the curable resin layer 3 may be, for example, 10 to 2000 mJ/cm² or 100 to 1500 mJ/cm², although depending on a processing area or the cost of processing equipment.

As the optical system of the excimer laser light 15, a condensing optical system or an imaging optical system can be used. When the curable resin layer 3 is processed into a predetermined pattern, it is preferable to use an imaging optical system from the viewpoint of throughput. The reduction projection magnification of the imaging optical system may be, for example, 1 to 300 times or 1 to 20 times.

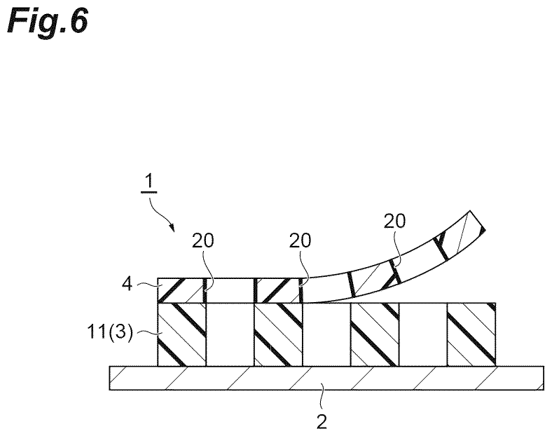

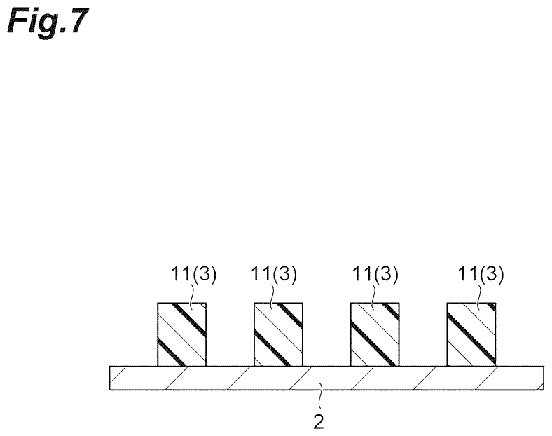

As illustrated in FIG. 6, the peeling step S04 is a step of peeling the support film 4 from the curable resin layer 3 after curing. The support film 4 is peeled off from the curable resin layer 3 by, for example, an auto-peeler. When the support film 4 is peeled off, the curable resin layer 3 after curing processed into a line shape is formed on the substrate 2, as illustrated in FIG. 7. An irradiation mark (hole) corresponding to the irradiation of the excimer laser light 15 in the processing step is formed in the support film 4 to be peeled in the peeling step. Debris 20, occurring when the curable resin layer 3 is subjected to laser ablation processing, can adhere to the periphery of the irradiation mark. The debris 20 is, for example, charcoal occurring when the support film 4 is burnt by the irradiation with the excimer laser light 15. Since the debris 20 adheres to the side of the support film 4, the step of cleaning the debris of the curable resin layer 3 can be omitted, leading to simplification of the steps of the pattern forming method.

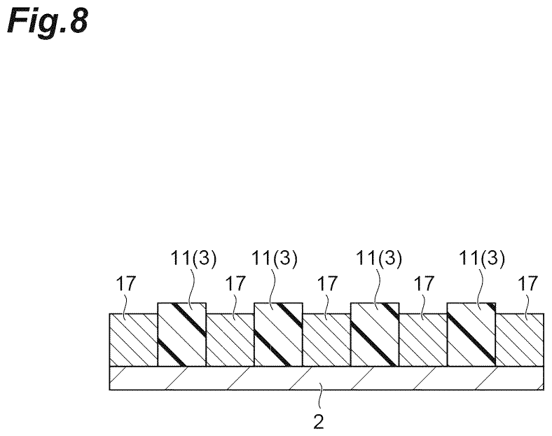

The forming step S05 is a step of forming the wiring pattern 16 on the substrate. In the forming step, a plating layer 17 is formed using the curable resin layer 3 of a predetermined pattern as a mask, as illustrated in FIG. 8. Examples of the constituent material of the plating layer 17 include Cu, Ni, and Sn. As a method for forming the plating layer 17, for example, electroplating can be used. In forming the plating layer 17, the surface of the substrate 2 may be subjected to a desmear treatment in advance, and a seed layer for forming the plating layer 17 may be provided on the surface.

After the formation of the plating layer 17, the curable resin layer 3 is removed, and the wiring pattern 16 formed of the plating layer 17 is formed on the substrate 2, as illustrated in FIG. 9. When the seed layer is formed on the surface of the substrate 2, the seed layer is removed by etching or the like after the curable resin layer 3 is removed, and the wiring patterns 16, 16 are electrically separated from each other. Examples of the method for removing the curable resin layer 3 include a wet peeling method using an inorganic alkaline aqueous solution or an organic alkaline aqueous solution and an organic solvent, and a dry etching method using a plasma treatment.

As the base of the alkaline aqueous solution used in the wet peeling method, for example, alkali hydroxide such as hydroxide of lithium, sodium, or potassium; alkaline carbonate such as carbonate or bicarbonate of lithium, sodium, potassium, or ammonium; alkali metal phosphate such as potassium phosphate or sodium phosphate; alkali metal pyrophosphate such as sodium pyrophosphate or potassium pyrophosphate; borax (sodium tetraborate); sodium metasilicate; tetramethylammonium hydroxide; ethanolamine; ethylenediamine; diethylenetriamine; 2-amino-2-hydroxymethyl-1,3-propanediol; 1,3-diamino-2-propanol; morpholine; or the like, is used. Examples of the wet peeling method include methods using a dipping method, a paddle method, a spraying method, brushing, slapping, scrubbing, rocking immersion, and the like.

In the present embodiment, the line-and-space L/S of the wiring pattern 16 obtained after the forming step is 5/5 μm or less. That is, in the present embodiment, a line width L of the wiring pattern 16 is 5 μm or less, and an interval S between the adjacent wiring patterns 16, 16 is 5 μm or less. In addition, in the present embodiment, an aspect ratio of the wiring pattern 16 (a ratio of a height H of the wiring pattern 16 to the line width L of the wiring pattern 16) is 0.5 to 20. The aspect ratio of the wiring pattern 16 may be 1 to 10.

In this pattern forming method, the entire curable resin layer 3 is cured before the curable resin layer 3 is processed into a predetermined pattern by the excimer laser light 15, as described above. This makes it possible to suppress refraction of the excimer laser light 15 in the curable resin layer 3 during the processing of the curable resin layer 3 after curing. Also, in this pattern forming method, the curable resin 3 after curing is irradiated with the excimer laser light 15 from the side of the support film 4 during the processing of the curable resin layer 3 after curing. Therefore, the support film 4 functions as a protective material for protecting the processed surface of the curable resin layer 3 after curing. Therefore, in this pattern forming method, occurrence of a defect in the curable resin 3 during the processing is suppressed, and a miniaturized pattern can be accurately formed.

In the present embodiment, the line-and-space L/S of the wiring pattern 16 is 5/5 μm or less. In this pattern forming method, occurrence of a defect in the curable resin layer 3 in the processing step can be suppressed as described above. Therefore, it is suitable for forming the miniaturized wiring pattern 16 having a line-and-space L/S of 5/5 μm or less.

In the present embodiment, the aspect ratio of the wiring pattern 16 is 0.5 to 20. In this pattern forming method, occurrence of a defect in the curable resin layer in the processing step can be suppressed as described above. Therefore, it is suitable for forming a miniaturized wiring pattern having an aspect ratio of 1 to 10.

In the present embodiment, the curable resin layer 3 includes the photocurable resin 11. As a result, the entire curable resin layer 3 can be easily cured by light irradiation.

The present disclosure is not limited to the above embodiment. For example, the curable resin layer 3 may include a thermosetting resin. In this case, the entire curable resin layer 3 can be easily cured by heating. As the thermosetting resin, for example, a phenol resin, an epoxy resin, a melamine resin, an alkyd resin, a silicone resin, a thermosetting polyimide, or the like can be used. When the thermosetting resin is used, the curing condition in the curing step S02 can be set to, for example, 30 minutes or longer at a temperature of 120° C. or higher in an oven.

### REFERENCE SIGNS LIST

2 Substrate
3 Curable resin layer
4 Support film
11 Photocurable resin
14 Mask
15 Excimer laser light
16 Wiring pattern
17 Plating layer

1. A pattern forming method comprising:
laminating a curable resin layer and a support film on a substrate;
curing the entire curable resin layer;
processing the curable resin layer into a predetermined pattern by irradiating the curable resin layer after curing with excimer laser light from a side of the support film through a mask;
peeling the support film from the curable resin layer after processing; and
forming a plating layer using the curable resin layer after processing as a mask, and then removing the curable resin to form a wiring pattern by the plating layer on the substrate.

2. The pattern forming method according to claim 1, wherein a line-and-space L/S of the wiring pattern is 5/5 μm or less.

3. The pattern forming method according to claim 1, wherein an aspect ratio of the wiring pattern is 0.5 to 20.

4. The pattern forming method according to claim 1, wherein the curable resin layer includes a photocurable resin.

5. The pattern forming method according to claim 1, wherein the curable resin layer includes a thermosetting resin.
